(19) United States
(12) Patent Application Publication
(10) Pub. No.: US 2023/0411341 A1
(43) Pub. Date: Dec. 21, 2023

(54) SEMICONDUCTOR DEVICE AND METHOD FOR MANUFACTURING SEMICONDUCTOR DEVICE

(71) Applicant: SONY GROUP CORPORATION, Tokyo (JP)

(72) Inventors: Koichi ONO, Tokyo (JP); Mika KOTANAGI, Tokyo (JP)

(73) Assignee: SONY GROUP CORPORATION, Tokyo (JP)

(21) Appl. No.: 18/253,628

(22) PCT Filed: Nov. 16, 2021
(86) PCT No.: PCT/JP2021/042077

§ 371 Date: May 19, 2023

(30) Foreign Application Priority Data
Nov. 26, 2020 (JP) 2020-195656

(51) Int. Cl. H01L 23/00; H01L 23/14; H01L 23/498

(52) U.S. Cl. CPC H01L 24/48; H01L 23/142; H01L 23/49816; H01L 24/16; H01L 24/32; H01L 24/73; H01L 24/85; H01L 2924/3511; H01L 2224/32221; H01L 2224/48221; H01L 2224/73265; H01L 2224/85

(57) ABSTRACT

Provided are a semiconductor device having a stress alleviation structure in which resistance to stress concentrated on a predetermined portion of the semiconductor device is improved, and a method for manufacturing the semiconductor device. The semiconductor device includes: a first dielectric layer; a seed layer having a first land portion formed on the first dielectric layer; a second land portion formed on the seed layer and having a diameter larger than a diameter of the first land portion that can be connected to the wiring pattern; an external terminal formed on the second land portion; and a second dielectric layer covering the seed layer, the first land portion, and the second land portion.

### TECHNICAL FIELD

The present disclosure relates to a semiconductor device having a stress alleviation structure such as a redistribution layer (RDL) or an external terminal, and a method for manufacturing the same.

### BACKGROUND ART

Conventionally, as the demand for miniaturization of electronic devices has increased, the need for miniaturization and high-density mounting of semiconductor dies has increased, and in response to this, unique packaging technologies have appeared.

Examples of such a packaging system include a package on package (PoP), a fine pitch ball grid array (FBGA), a wafer level chip size package (WLCSP), and a fan out wafer chip level package (FOWLP) which is further developed from them. In any package form, a problem occurrence rate such as disconnection of wiring at the time of manufacturing or after shipment increases as the accumulation density is improved, and improvement of reliability by stress alleviation applied to the wiring is required.

Copper (Cu) having a small volume resistivity is frequently used as a conductive material of a redistribution layer or interposer board wiring of a semiconductor device. For example, a copper wiring pattern is provided on silicon oxide (SiO₂) which is an insulating layer of a silicon substrate.

However, while the linear expansion coefficient of silicon is 2×10⁻⁶ (1/K), the linear expansion coefficient of copper is about 17×10⁻⁶ (1/K), which is about 8.5 times as large as that of silicon. For this reason, a thermal expansion difference is generated between silicon and copper due to self-heating of the semiconductor device, a temperature change due to ambient temperature or radiant heat from the outside, or the like. As a result, stress concentrates on the periphery of the solder joint having a small degree of freedom in terms of strength due to expansion and contraction of copper. Then, due to repetition of the temperature change (heat cycle), cracks due to thermal fatigue are generated in the solder joint and the wiring pattern, and finally disconnection occurs.

Specifically, stress is most likely to be applied to a portion where the redistribution layer or the interposer board of the semiconductor device and the edges of the dies mounted on the redistribution layer or the interposer substrate overlap with each other. Therefore, disconnection is likely to occur in the copper pattern wired in the portion where the edges of the dies overlap. In addition, stress is also likely to be applied to a root portion of an external terminal or a via, and disconnection or peeling is likely to occur in a copper pattern wired to these portions.

According to the configuration disclosed in Patent Document 1, a first integrated circuit die, a sealing material around the first integrated circuit die, and a conductive line electrically connecting a first conductive via to a second conductive via are included. The conductive line includes a first segment on the first integrated circuit die and a second segment having a first lengthwise dimension extending in a first direction and a second lengthwise dimension extending in a second direction different from the first direction. The second segment extends on a boundary between the first integrated circuit die and the sealing material. That is, it is intended to improve resistance to stress by redundantly routing the wiring pattern in plan view.

### CITATION LIST

### Patent Document

Patent Document 1: U.S. Pat. No. 9,741,690

### SUMMARY OF THE INVENTION

### Problems to be Solved by the Invention

However, the technique disclosed in Patent Document 1 has a problem that the wiring pattern becomes long, which increases line resistance, inductance, and capacitance, and causes signal attenuation and a delay in propagation time, which hinders high-speed transmission. In addition, there is a problem that a wiring space is required to redundantly route the wiring pattern, and the degree of integration cannot be increased.

The present disclosure has been made in view of the above-described problems, and an object of the present disclosure is to provide a semiconductor device having a stress alleviation structure in which resistance to stress concentrated on a predetermined portion such as a wiring pattern, an external terminal, and a root portion of a via is improved, and a method for manufacturing the semiconductor device.

### Solutions to Problems

The present disclosure has been made to solve the above-described problems, and a first aspect of the present disclosure is a semiconductor device including: a first dielectric layer; a seed layer having a first land portion formed on the first dielectric layer; a second land portion formed on the seed layer and having a diameter larger than a diameter of the first land portion that can be connected to the wiring pattern; an external terminal formed on the second land portion; and a second dielectric layer covering the seed layer, the first land portion, and the second land portion.

Further, in the first aspect, the wiring pattern may be formed by forming a land portion formed on the seed layer in a substantially circular shape in plan view and extending a line portion.

Further, in the first aspect, the wiring pattern may be formed by connecting land portions formed on two of the seed layer formed in the substantially circular shape in plan view in series and extending a line portion.

Further, in the first aspect,
a land portion formed on the seed layer may be formed in a substantially tapered shape expanded upward.

Further, a second aspect of the present invention is a semiconductor device including:
a conductive pad recessed in a passivation layer;
a seed layer having a land portion formed on the conductive pad;
an under bump metal layer including upper and lower two layers formed on the seed layer;
an external terminal formed on the under bump metal layer; and
a dielectric layer covering a peripheral surface of the under bump metal layer,
in which a diameter of a lower layer of the under bump metal layer is formed to be larger than a diameter of the land portion of the seed layer.

Further, in the second aspect, a lower layer of the under bump metal layer formed on the seed layer may be formed in a substantially tapered shape expanded upward.

In addition, a third aspect of the present invention is a method for manufacturing a semiconductor device, the method including: forming a redistribution layer on a silicon substrate and forming a conductive pad thereon; covering the redistribution layer with a resin film and forming an opening on the conductive pad; forming a conductive seed layer on the opening of the conductive pad and an upper surface of the resin film; forming an under bump metal layer of a conductor on the seed layer in the opening of the conductive pad; forming a solder bump on the under bump metal layer; and performing side edging on the seed layer to form a diameter of a lower layer of the under bump metal layer larger than a diameter of a land portion formed by the seed layer.

Further, in the third aspect, the forming the under bump metal layer may include performing copper plating on a lower layer and nickel plating on an upper layer.

Further, in the third aspect, the forming the under bump metal layer may include performing sputtering of copper on a lower layer and nickel plating on an upper layer.

Further, in the third aspect, the forming the under bump metal layer may include forming an end surface of an outer periphery of a lower under bump metal layer in a tapered shape expanded upward.

By adopting the above aspects, it is possible to alleviate stress concentrated on the redistribution layer immediately below the die edge, the interposer board, and/or the root portion of the external terminal or the via due to a difference in linear expansion coefficient between copper and silicon and a temperature change.

### BRIEF DESCRIPTION OF DRAWINGS

FIG. 1 is a schematic cross-sectional view illustrating a configuration example of a package of a semiconductor device to which a stress alleviation structure according to the present disclosure is applied.

FIG. 2 is a schematic cross-sectional view obtained by rotating the configuration example of FIG. 1 by 180 degrees.

FIG. 3 is a partially enlarged view of a portion M in FIG. 1.

FIG. 4 is a cross-sectional view of an external terminal of the semiconductor device having the stress alleviation structure according to a first embodiment of the present disclosure.

FIG. 5 is a plan view of a land portion of an external terminal of a semiconductor device having a stress alleviation structure according to the first embodiment and a second embodiment of the present disclosure.

FIG. 6 is a cross-sectional view of an external terminal of the semiconductor device having the stress alleviation structure according to the second embodiment of the present disclosure.

FIG. 7 is a plan view of a land portion and a wiring line portion of an external terminal of a semiconductor device having a stress alleviation structure according to a third embodiment of the present disclosure.

FIG. 8 is a view schematically illustrating a method for manufacturing the external terminal of the semiconductor device having the stress alleviation structure according to the second embodiment (part 1).

FIG. 9 is a view schematically illustrating the method for manufacturing the external terminal of the semiconductor device having the stress alleviation structure according to the second embodiment (part 2).

FIG. 10 is a view schematically illustrating the method for manufacturing the external terminal of the semiconductor device having the stress alleviation structure according to the second embodiment (part 3).

FIG. 11 is a view schematically illustrating the method for manufacturing the external terminal of the semiconductor device having the stress alleviation structure according to the second embodiment (part 4).

FIG. 12 is a schematic cross-sectional view illustrating an example of a wiring pattern of a semiconductor device having a stress alleviation structure according to the present disclosure.

FIG. 13 is a plan view of a wiring pattern of a semiconductor device having a stress alleviation structure according to the present disclosure (part 1).

FIG. 14 is a plan view of a wiring pattern of a semiconductor device having a stress alleviation structure according to the present disclosure (part 2).

FIG. 15 is a plan view of a wiring pattern of a semiconductor device having a stress alleviation structure according to the present disclosure (part 3).

FIG. 16 is a plan view of a wiring pattern of a semiconductor device having a stress alleviation structure according to the present disclosure (part 4).

FIG. 17 is a plan view of a wiring pattern of a semiconductor device having a stress alleviation structure according to the present disclosure (part 5).

FIG. 18 is a schematic cross-sectional view of a wiring pattern of a semiconductor device having a stress alleviation structure according to the present disclosure.

FIG. 19 is a plan view of a power supply pattern of a semiconductor device having a stress alleviation structure according to the present disclosure (part 1).

FIG. 20 is a plan view of a power supply pattern of a semiconductor device having a stress alleviation structure according to the present disclosure (part 2).

FIG. 21 is a plan view of a power supply and a wiring pattern of a semiconductor device having a stress alleviation structure according to the present disclosure (part 3).

FIG. 22 is a cross-sectional view in a case where the semiconductor device having the stress alleviation structure of the present disclosure is applied to a WLCSP package.

FIG. 23 is a cross-sectional view in a case where the semiconductor device having the stress alleviation structure of the present disclosure is applied to an FBGA package.

FIG. 24 is a cross-sectional view in a case where the semiconductor device having the stress alleviation structure of the present disclosure is applied to a wire bonding FBGA package.

FIG. 25 is a cross-sectional view in a case where the semiconductor device having the stress alleviation structure of the present disclosure is applied to a package on which an integrated circuit die is mounted on a substrate.

### MODE FOR CARRYING OUT THE INVENTION

Next, modes for carrying out the technology according to the present disclosure (hereinafter, referred to as “embodiments”) will be described in the following order with reference to the drawings. Note that, in the following drawings, the same or similar parts are denoted by the same or similar reference numerals. In addition, the drawings are schematic, and dimensional ratios and the like of the respective parts do not necessarily match actual ones. In addition, it is needless to say that the drawings include parts having different dimensional relationships and ratios.
1. Configuration Example of Semiconductor Device Having Stress Alleviation Structure According to Present Disclosure
2. Configuration Example of Semiconductor Device Having Stress Alleviation Structure According to First Embodiment
3. Configuration Example of Semiconductor Device Having Stress Alleviation Structure According to Second Embodiment
4. Configuration Example of Semiconductor Device Having Stress Alleviation Structure According to Third Embodiment
5. Example of Method for Manufacturing Semiconductor Device Having Stress Alleviation Structure According to Second Embodiment
6. Wiring Pattern Example of Semiconductor Device Having Stress Alleviation Structure According to Present Disclosure
7. Power Supply Pattern Example of Semiconductor Device Having Stress Alleviation Structure According to Present Disclosure
8. Example of Semiconductor Device to Which Stress Alleviation Structure According to Present Disclosure Is Applicable

### <1. Configuration Example of Semiconductor Device Having Stress Alleviation Structure According to Present Disclosure>

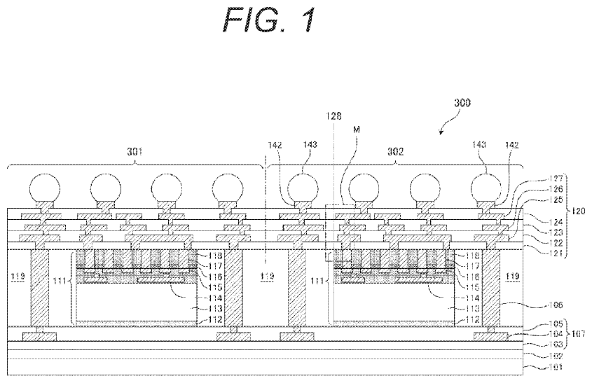

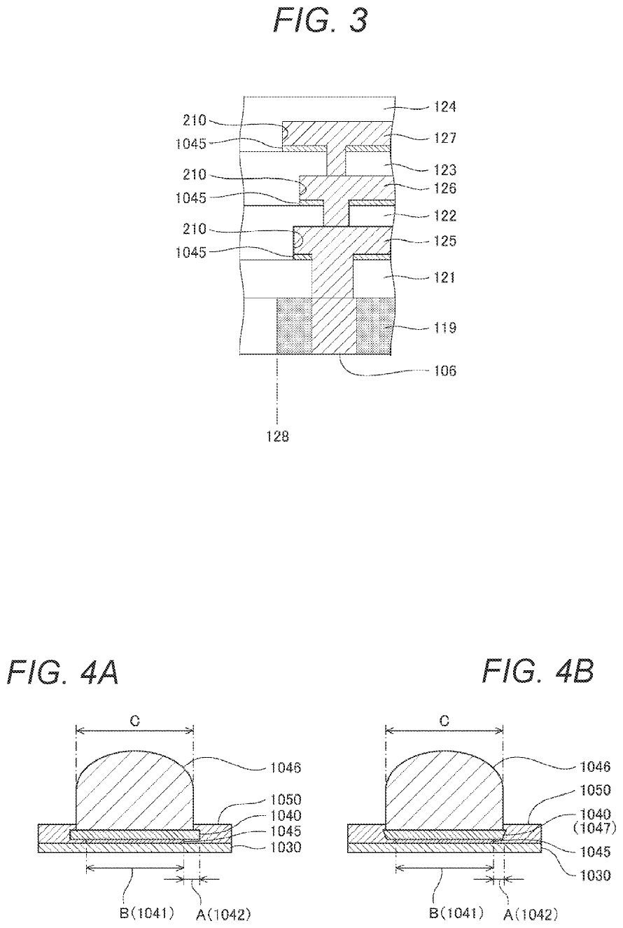

FIG. 1 is a schematic cross-sectional view illustrating a configuration example of a package 300 of a semiconductor device 500 to which a stress alleviation structure according to the present disclosure is applied. Furthermore, FIG. 3 is a partially enlarged view of a portion M in FIG. 1. In FIG. 1, a release layer 102 is formed on a carrier substrate 101. In addition, respective regions for forming a first package region 301 and a second package region 302 are continuously provided. When the assembly is completed, these are divided into individual semiconductor devices 500. Note that the number of the continuous package regions is not limited to two.

The carrier substrate 101 may be constituted by glass or ceramic, or may be a wafer capable of simultaneously forming a plurality of package regions on the carrier substrate 101. The release layer 102, along with the carrier substrate 101, is ultimately removed from the package 300 formed in the manufacturing process. One example of a material for the release layer 102 is an epoxy-based thermal release material that loses its adhesion when heated, for example, a light-to-heat-conversion (LTHC) release coating.

A dielectric layer 103 and a wiring pattern 104 are formed on the release layer 102. A material of the dielectric layer 103 is, for example, a polymer such as polybenzoxazole (PBO), a nitride such as silicon nitride, or an oxide such as silicon oxide. The dielectric layer 103 is formed by any acceptable deposition process, such as spin coating, chemical vapor deposition (CVD), lamination, or the like, or a combination thereof.

The wiring pattern 104 is formed on the dielectric layer 103. As an example of a method for forming the wiring pattern 104, a seed layer (not illustrated) is formed on the dielectric layer 103. The seed layer is a metal layer, which may be constituted by a single layer or a plurality of layers constituted by different materials. An example of the seed layer may be constituted by a titanium (Ti) layer and a copper layer over the titanium layer. The seed layer may be formed using, for example, PVD or the like. The optimum thickness of the seed layer for forming the wiring pattern 104 is 50 nm to 200 nm.

The wiring pattern 104 is formed by forming a photoresist (not illustrated) on the seed layer, patterning the photoresist to form an opening in the photoresist by etching, plating a conductive material on the photoresist, removing the unnecessary resist by ashing, and removing the exposed portion of the seed layer by etching or the like.

Here, although details will be described later, the wiring pattern 104 constituted by a conductive material may have a first portion in contact with the seed layer and a second portion not in contact with the seed layer. Since the seed layer is not formed immediately below the second portion of the conductive material, the wiring pattern 104 can be deformed or moved following stress from the outside or the like, and the stress can be effectively alleviated. In addition, in a case where a through via 106, an external terminal such as a conductive pillar or a solder ball, or a via, which will be described later, is formed on the wiring pattern 104, stress applied to the root portion of the external terminal or via can be reduced.

A dielectric layer 105 is formed on the dielectric layer 103 and the wiring pattern 104. The dielectric layer 105 is constituted by a similar material to that of the dielectric layer 103. Note that the dielectric layers 103 and 105 and the wiring pattern 104 may be referred to as a back surface redistribution layer 107. As illustrated in FIG. 1, the back surface redistribution layer 107 includes two dielectric layers 103 and 105 and one wiring pattern 104. The back surface redistribution layer 107 can include any number of dielectric layers 103 and 105, wiring patterns 104, and through vias 106.

The through via 106 connects the vertically adjacent wiring patterns 104 to each other. The through via 106 is formed by opening the dielectric layer 105 and erecting a conductive material electrically connected to the wiring pattern 104 and the seed layer.

An integrated circuit die 111 is secured to the dielectric layer 105 of each of the first package region 301 and the second package region 302 with an adhesive 112. The integrated circuit die 111 may be a logic die (for example, a central processing unit, a microcontroller, or the like), a memory die (for example, a dynamic random access memory (DRAM) die, a static random access memory (SRAM) die, or the like), a power management integrated circuit die, a radio frequency (RF) die, a sensor die, a microelectromechanical systems (MEMS) die, a signal processing die (for example, a digital signal processing (DSP) die), a front end die (for example, an analog front end (AFE) die), the like, or a combination thereof. Each integrated circuit die 111 includes a semiconductor substrate 113 constituted by silicon and may be interconnected by an interconnect structure 114 formed in a dielectric layer to form an integrated circuit.

Furthermore, in a case where a plurality of integrated circuit dies 111 and dummy dies is fixed, the integrated circuit dies may have different sizes (for example, different heights and/or surface areas), and in other embodiments, the integrated circuit dies 111 may have the same size (for example, the same height and/or surface area). In addition, a dummy die for the purpose of preventing warpage and alleviating stress may be fixed.

The integrated circuit die 111 further includes pads 115, such as aluminum (Al) pads, to which external connections are made. The pads 115 are on the active surface on which circuits are formed in the integrated circuit die 111. A passivation (PV) film 116 is formed on the integrated circuit die 111 and parts of the pads 115. A die connector 117 such as a conductive pillar (for example, constituted by a metal such as copper) penetrates the pad 115 from the opening of the passivation film 116. That is, the die connector 117 is mechanically and electrically coupled to each pad 115 via the passivation film 116. The die connector 117 may be formed by, for example, plating or the like, and electrically couples each integrated circuit of the integrated circuit die 111.

Note that, in the integrated circuit die 111, a single layer or a plurality of redistribution layers may be formed on the pad 115 and the passivation film 116. The formation process is similar to that of the back surface redistribution layer 107 described above. In this case, the die connector 117 is connected to the wiring of the uppermost layer of the redistribution layer. By forming such a redistribution layer, it is possible to alleviate the gap between the wiring pitch of the integrated circuit die 111 and the wiring pitch of the die connector 117.

In addition, the conductive material constituting the wiring pattern 104 may have a first portion in contact with the seed layer and a second portion in non-contact with the seed layer. With such a configuration, since the seed layer is not formed immediately below the second portion of the conductive material, the wiring pattern 104 can be deformed or moved following the stress from the outside or the like, and the stress can be effectively alleviated. In addition, in a case where terminals such as the die connector 117 and the through via 106 to be described later are formed on the wiring pattern 104, stress applied to root portions of these terminals can be reduced. Note that the gap width A between the first portion and the second portion is preferably, for example, 50 nm or more and 1000 nm or less.

A dielectric material 118 is formed on the active surface side of integrated circuit die 111. The dielectric material 118 is formed to seal the die connector 117. The dielectric material 118 may be a polymer, a nitride such as silicon nitride, an oxide such as silicon oxide, or a combination thereof.

As illustrated in FIG. 1, the adhesive 112 adheres the integrated circuit die 111 to the back surface redistribution layer 107 including the dielectric layer 105 and the like. The adhesive 112 may be applied to the back surface of the integrated circuit die 111, for example, the back surface of each semiconductor wafer, or may be applied onto the surface of the dielectric layer 105.

A sealing material 119 is a molding compound (for example, epoxy resin), and is molded by a method such as compression molding or transfer molding. Then, after being cured by heat or light, the upper surfaces of the through via 106, the die connector 117, and the sealing material 119 are ground to have a flattened shape.

On the integrated circuit 111, wiring patterns 125, 126, and 127 and dielectric layers 121, 122, 123, and 124 electrically connected in the vertical direction are alternately formed by the through via 106 to form a front surface redistribution layer 120.

An example of the film thickness of the dielectric layers 121, 122, 123, and 124 is 1 μm to 10 μm, but is preferably 5 μm or less from the viewpoint of height reduction. An example of the film thickness of each of the wiring patterns 125, 126, and 127 is 0.5 μm to 4 μm, and is desirably 2 μm or less from the viewpoint of height reduction.

On the wiring pattern 127, an under bump metal (hereinafter referred to as “UBM”) 142 is formed on the outer surface of the front surface redistribution layer 120. A conductive connector 143 is formed on the UBM 142. The UBM 142 is used to couple to the conductive connector 143, and opens the dielectric layer 124 and is connected to the wiring pattern 127.

The conductive connector 143 formed on the UBM 142 is a ball grid array (BGA) connector, a solder ball, a metal column, a C4 bump, a micro-bump, a bump formed by an electroless nickel-electroless palladium-immersion gold technique (ENEPIG), or the like.

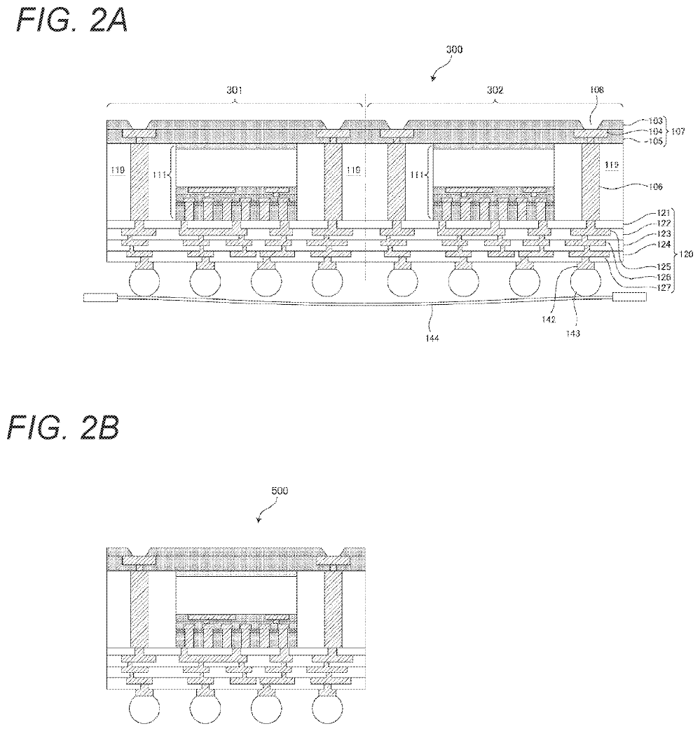

FIG. 2A is a diagram in which the package 300 including the first package region 301 and the first package region 302 illustrated in FIG. 1 is rotated by 180 degrees so that the vertical direction is reversed. The carrier substrate 101 illustrated in FIG. 1 is released from the dielectric layer 103 of the back surface redistribution layer 107 along with the epoxy-based release layer 102. The carrier substrate 101 can be released by irradiating the release layer 102 with light such as laser light or UV light.

As illustrated in FIG. 2A, the package 300 is turned over and placed on a tape 144. Then, an opening 108 for exposing a part of the wiring pattern 104 is formed in the dielectric layer 103. The opening 108 is formed using, for example, laser drilling, etching, or the like, and is formed to be usable for a package-on-package or the like. Note that the package 300 is cut along a predetermined scribe line region to divide the first package region 301 and the second package region 302. As a result, as illustrated in FIG. 2B, the semiconductor device 500 can be obtained.

### <2. Configuration Example of Semiconductor Device Having Stress Alleviation Structure According to First Embodiment>

### [Basic Configuration Example of First Embodiment]

A basic configuration example of a semiconductor device having a stress alleviation structure according to a first embodiment will be described with reference to the drawings. As described above, the front surface redistribution layer 120 is formed by alternately laminating the wiring patterns 125, 126, and 127, which are conductive materials, and the dielectric layers 121, 122, 123, and 124. Then, as illustrated in FIG. 3 enlarging the portion M in FIG. 1, the wiring patterns 125, 126, and 127 are in contact with a seed layer 1045 formed on the upper surface of each of the dielectric layers 121, 122, and 123.

The seed layer 1045 is constituted by titanium which is a hard metal. On the other hand, the wiring patterns 125, 126, and 127 are constituted by, for example, copper, which is a metal softer than titanium. In addition, the linear expansion coefficient of titanium is 8.4×10⁻⁶ (1/K), whereas the linear expansion coefficient of copper is about 17×10⁻⁶ (1/K), and copper has a larger expansion rate due to temperature.

In addition, the seed layer 1045 and the wiring pattern 125 sandwiched between the dielectric layer 121 and the dielectric layer 122 are formed such that their end surfaces 210 are conventionally formed on substantially the same plane as illustrated in FIG. 3 by etching in the formation process.

Here, the wiring pattern 125 continuously repeats expansion and contraction due to reflow or a temperature change during use. However, the wiring pattern 125 receives pressure from the dielectric layers 122, 123, and 124 and the wiring patterns 126 and 127 laminated thereon from above. In addition, the movement is restricted by the seed layer 1045 constituted by titanium which is a hard material from below. Therefore, since the degree of freedom of the wiring pattern 125 is significantly limited, stress due to the difference in linear expansion coefficient is concentrated on the end surface 210 by repeatedly receiving a temperature change, and disconnection easily occurs at a portion of the end surface 210.

In addition, similarly, stress is also concentrated on the root portions of the external terminals and the vias, so that these root portions are easily peeled off.

In addition, as illustrated in FIGS. 1 and 3, the integrated circuit die 111 is fixed below the front surface redistribution layer 120. Then, the integrated circuit die 111 and the front surface redistribution layer 120 are sealed with the sealing material 119 that is a molding compound (for example, epoxy resin). Thus, a boundary 128 is formed between the integrated circuit die 111 and the front surface redistribution layer 120.

Then, since the linear expansion coefficients of the material of the integrated circuit die 111 and the sealing material 119 do not match, bending of the device package occurs at the boundary 128 between the integrated circuit die 111 and the sealing material 119. As a result, stress is applied to the wiring pattern 125 in the vicinity of the boundary 128.

Also due to such a cause, disconnection is likely to occur in the wiring pattern 125 in the vicinity of the boundary 128.

In the semiconductor device 500 having the stress alleviation structure according to the present disclosure, as illustrated in FIG. 4A, a wiring pattern 1040 includes a first portion 1041 (B in the figure) in contact with the seed layer 1045 and a second portion 1042 (A in the figure) not in contact with the seed layer 1045. With such a configuration, since the seed layer 1045 is not formed immediately below the second portion 1042 of the wiring pattern 1040, the wiring pattern 1040 can be deformed or moved following stress generated by external pressure or temperature change, and the stress can be effectively alleviated.

In addition, in a case where an external terminal or a via such as a through via 106, a conductive pillar, or a solder ball, which will be described later, is formed on the wiring patterns 125, 126, and 127, it is possible to reduce stress applied to the root portion of the external terminal or via.

In addition, stress generated in the vicinity of the boundary 128 between the material of the integrated circuit die 111 and the sealing material 119 can be reduced by routing a wiring path to be described later, a thickness of the wiring path, an entry angle to the boundary 128, use of a power supply pattern, or the like.

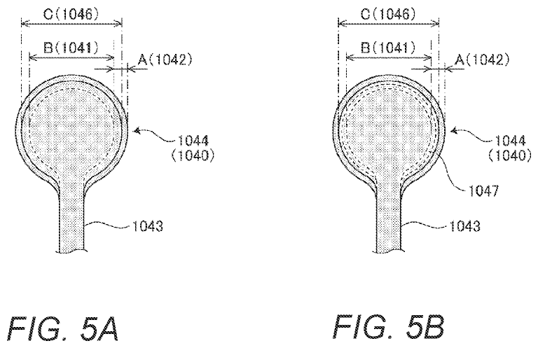

First, the first portion 1041 in contact with the seed layer 1045 and the second portion 1042 in non-contact will be described in more detail with reference to FIGS. 4A and 4B and FIGS. 5A and 5B. FIG. 4A is a cross-sectional view in which the seed layer 1045 is formed on a dielectric layer 1030, the wiring pattern 1040 is formed thereon to remove an unnecessary region of the seed layer 1045, and an external terminal 1046 electrically connected to a dielectric layer 1050 and the wiring pattern 1040 is formed on the dielectric layer 1030 and the wiring pattern 1040.

In addition, FIG. 5A is a plan view of a land portion 1044 of the external terminal 1046 which is the wiring pattern 1040 illustrated in FIG. 4A. As illustrated in FIG. 5A, the wiring pattern 1040 includes a line portion 1043 and the land portion 1044.

As illustrated in FIG. 4A, the wiring pattern 1040 of the land portion 1044 includes the first portion 1041 in contact with the seed layer 1045 and the second portion 1042 not in contact with the seed layer 1045. That is, the first portion 1041 is a portion overlapping the seed layer 1045. In addition, the second portion 1042 is a portion that does not overlap the seed layer 1045.

In addition, the second portion 1042 may be depleted (air layer), but may be filled with the dielectric layer 1050 as illustrated in FIGS. 4A and 4B. According to this, in a case where the dielectric layer 1050 is softer than the seed layer 1045, the degree of freedom of the wiring pattern 1040 is improved, and stress can be alleviated.

The second portion 1042 can be formed by over-etching the region of the wiring pattern 1040 when the seed layer 1045 is removed by the etching process using the wiring pattern 1040 as a mask. In the case of wet etching, the etching amount can be controlled by time, for example, so that the etchant enters the inside of the region of the wiring pattern 1040. A specific example of a manufacturing method for forming the second portion 1042 will be described later.

With such a configuration, since the seed layer 1045 is not formed immediately below the second portion 1042 of the wiring pattern 1040, the movement of the wiring pattern 1040 is not restricted by the seed layer 1045. As a result, the wiring pattern 1040 can be deformed or moved following the stress from the outside, and the stress can be effectively alleviated.

In addition, in a case where the through via 106, the external terminal 1046 (FIG. 4A illustrates an example of a solder ball) such as a conductive pillar or a solder ball, or a via (not illustrated) is formed on the wiring pattern 1040, stress applied to the root portion of the external terminal 1046 or the via can be reduced.

The width A of the second portion 1042 is preferably 50 nm or more and 1000 nm or less in a case where the wiring pattern 1040 is constituted by copper having a film thickness of about 5 μm.

In addition, the width B of the first portion 1041 and the width C of the exposed portion (the opening of the dielectric layer 1050) of the wiring pattern 1040 may have the following relationship.

B<C By having such a relationship, the seed layer 1045 is disposed inside the contact portion between the wiring pattern 1040 and the external terminal 1046 or the via, the degree of freedom of the wiring pattern 1040 and the external terminal 1046 or the via with respect to the stress applied to the exposed portion of the wiring pattern 1040 (stress applied to the root portion of the external terminal 1046 or the via) is further improved, and the stress can be effectively alleviated.

### [Modification of First Embodiment]

Next, a modification of the semiconductor device having the stress alleviation structure according to the first embodiment will be described. In the present modification, as illustrated in FIG. 4B, an end surface 1047 of the land portion 1044 of the wiring pattern 1040 is formed in a substantially tapered shape expanding upward. In terms of alleviating stress, the width A of the second portion 1042 is desirably larger. However, if the thickness is too large, there may be a problem that the wiring pattern 1040 is peeled off. Therefore, by forming the end surface 1047 of the land portion 1044 in a tapered shape, the stress applied to the exposed portion of the wiring pattern 1040 is alleviated without increasing the width A of the second portion 1042.

FIG. 5B is a plan view of the land portion 1044 of the external terminal 1046 which is the wiring pattern 1040 in FIG. 4B. Similarly to the case of FIG. 5A, the wiring pattern 1040 includes the line portion 1043 and the land portion 1044 as illustrated in FIG. 5B. Then, in the wiring pattern 1040, the second portion 1042 is formed on an entire circumference of the first portion 1041 except for a connection portion between the line portion 1043 and the land portion 1044. In addition, the second portion 1042 is formed to have a substantially constant width (excluding the vicinity of the connection portion of the line portion 1043 and the land portion 1044) over the entire circumference of the first portion 1041.

In this case, what contributes to the degree of freedom of the wiring pattern 1040, the external terminal 1046, or the via (not illustrated) is the sum of the gap between the end of the upper surface and the end of the lower surface of the wiring pattern 1040 and the distance from the end of the lower surface of the wiring pattern 1040 to the end of the seed layer 1045 (that is, the width A of the second portion 1042). Therefore, in a case where the coverage of the seed layer 1045 with respect to the wiring pattern 1040 is maintained on one hand, and the relationship of B<C is particularly satisfied on the other hand, the degree of freedom of the wiring pattern 1040 and the external terminal 1046 or the via can be improved, and the stress can be effectively alleviated. The difference between the ends of the upper surface and the lower surface of the wiring pattern 1040 in the horizontal direction is desirably about 50 nm to 1000 nm.

In FIGS. 4B and 5B, the width of the upper surface of the wiring pattern 1040 and the width C of the exposed portion (the opening of the dielectric layer 1050) of the wiring pattern 1040 may substantially coincide with each other with a shift of 0 to several tens nm. That is, the external terminals 1046 such as solder balls, vias, and the like may be connected to the wiring pattern 1040 over the entire upper surface of the wiring pattern 1040. With such a configuration, the degree of freedom of the external terminal 1046 or the via by the second portion 1042 can be improved, and the effect of stress alleviation can be enhanced.

In a case where the land portion 1044 is formed on the dielectric layer 1030 with the seed layer 1045 interposed therebetween, the second portion 1042 of the land portion 1044 is disposed at a distance from the dielectric layer 1030. In addition, as described in FIGS. 4A and 5A, this interval may be depleted (air layer), but may be filled with the dielectric layer 1050. With such a configuration, the degree of freedom of the wiring pattern 1040 and the external terminal 1046 or the via is further improved, and the stress can be effectively alleviated. In addition, it is possible to reduce stress applied to the external terminal 1046 and the root portion of the via.

Configurations other than the above are similar to the case of the basic configuration example (FIG. 4A) of the first embodiment, and thus the description thereof will be omitted.

### <3. Configuration Example of Semiconductor Device Having Stress Alleviation Structure According to Second Embodiment>

### [Basic Configuration Example of Second Embodiment]

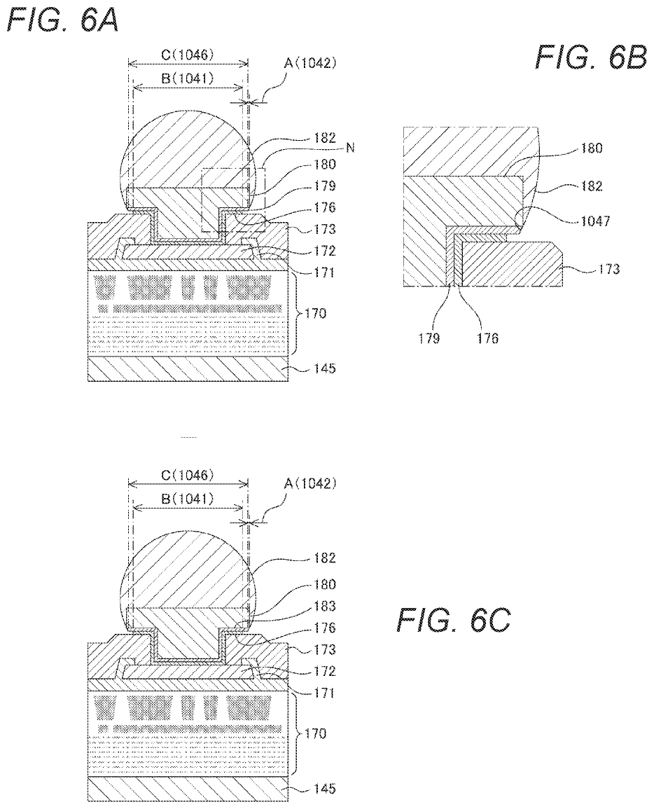

Next, a basic configuration example of a semiconductor device having a stress alleviation structure according to a second embodiment will be described. In the present basic configuration example, as illustrated in FIG. 6A, in a case where a line portion 1043 (wiring pattern 1040) (not illustrated in the figure) drawn from a copper under bump metal layer (hereinafter referred to as “UBM layer”) 179, a conductive connector 143, a through via 106, an external terminal 182 such as a solder ball, or the like is formed on the copper UBM layer 179, stress applied to root portions thereof is reduced.

FIG. 6A is a cross-sectional view illustrating an example in which UBM layers 179 and 180 are provided in a redistribution layer 170 and the external terminal 182 is provided thereon. As illustrated in FIG. 6A, the redistribution layer 170 is formed on the silicon substrate 145. Here, the redistribution layer 170 is not limited to the redistribution layer of the back surface redistribution layer 107 or the front surface redistribution layer 120. On the redistribution layer 170, an aluminum pad 172 having a substantially flat plate shape is recessed in the passivation layer 171.

A titanium seed layer 176 is formed on the aluminum pad 172 by sputtering. On the seed layer 176, the copper UBM layer 179 is formed by copper plating. On the copper UBM layer 179, the nickel UBM layer 180 having a substantially reverse convex shape is formed by nickel (Ni) plating. In the nickel UBM layer 180, a BGA which is the ball-shaped external terminal 182 is formed by solder reflow. Note that solder bumps (not illustrated) as projecting electrodes may be formed on the nickel UBM layer 180.

Then, similarly to the case of FIG. 4A in the basic configuration example of the first embodiment, the peripheral edge portion of the seed layer 176 is removed by etching by a predetermined depth (A). As a result, the first portion 1041 in contact with the seed layer 176 and the second portion 1042 in non-contact with the seed layer 176 are formed in the copper UBM layer 179 and the titanium seed layer 176. In addition, the shape of the copper UBM layer 179 in plan view is similar to that of FIG. 5A.

With such a configuration, it is possible to improve the degree of freedom of the external terminal 182 by the second portion 1042 and enhance the effect of stress alleviation. As a result, it is possible to reduce the stress applied to the line portion 1043 drawn out from the copper UBM layer 179 and the root portion of the external terminal 182.

Configurations other than the above are similar to the case of the basic configuration example (FIG. 4A) of the first embodiment, and thus the description thereof will be omitted.

### [Modification of Second Embodiment (Part 1)]

Next, a modification (part 1) of the semiconductor device having the stress alleviation structure according to the second embodiment will be described. FIG. 6B is a partially enlarged view of portion N in FIG. 6A. In the present modification, the end surface 1047 of the copper UBM layer 179 corresponding to the land portion 1044 of the wiring pattern 1040 in FIG. 4B is formed in a substantially tapered shape expanding upward as illustrated in FIG. 6B. That is, similarly to the case of the modification of the first embodiment described above, the end surface 1047 of the copper UBM layer 179 is formed in a tapered shape. Therefore, the shape of the copper UBM layer 179 in plan view is similar to that in FIG. 5B.

With such a configuration, stress applied to the exposed portion of the wiring pattern 1040 which is the line portion 1043 extended from the copper UBM layer 179 can be alleviated without increasing the width A of the second portion 1042. As a result, peeling of the wiring pattern 1040 is prevented, the degree of freedom of the external terminal 182 and the solder bump is further improved, and stress can be effectively alleviated. In addition, the stress applied to the root portion of the external terminal 182 or the like can be reduced.

Configurations other than the above are similar to the case of the basic configuration example (FIG. 6A) of the second embodiment, and thus the description thereof will be omitted.

### [Modification of Second Embodiment (Part 2)]

Next, a modification (part 2) of the semiconductor device having the stress alleviation structure according to the second embodiment will be described. In the present modification, in a case where the conductive connector 143, the through via 106, the external terminal 182 such as a solder ball, or the like is formed on the UBM layer, stress applied to root portions thereof is reduced.

FIG. 6C is a cross-sectional view illustrating an example in which UBM layers 183 and 180 are provided in the redistribution layer 170 and the external terminal 182 is provided thereon. As illustrated in FIG. 6C, the redistribution layer 170 is formed on the silicon substrate 145. Here, the redistribution layer 170 is not limited to a specific redistribution layer of the back surface redistribution layer 107 or the front surface redistribution layer 120.

On the redistribution layer 170, the aluminum pad 172 having a substantially flat plate shape is recessed in the passivation layer 171. The titanium seed layer 176 is formed on the aluminum pad 172 by sputtering. On the seed layer 176, the copper UBM layer 183 is formed by copper sputtering. On the copper UBM layer 183, the nickel UBM layer 180 having a substantially reverse convex shape is formed by nickel (Ni) plating. In the nickel UBM layer 180, the BGA which is the ball-shaped external terminal 182 is formed by solder reflow.

Then, similarly to the case of FIG. 4A in the basic configuration example of the first embodiment, the peripheral edge portion of the seed layer 176 is removed by etching by a predetermined depth (A). As a result, the first portion 1041 in contact with the seed layer 176 and the second portion 1042 in non-contact with the seed layer 176 are formed in the copper UBM layer 183 and the titanium seed layer 176.

With such a configuration, it is possible to improve the degree of freedom of the external terminal 182 by the second portion 1042 and enhance the effect of stress alleviation. As a result, the stress applied to the root portion of the external terminal 182 can be reduced. The present modification is effective in a case where the line portion 1043 is not drawn out from the UBM layer, and the external terminal 182 is only connected to the lower redistribution layer 170. That is, since the copper UBM layer 183 can be formed by sputtering of copper, the cost can be reduced.

Configurations other than the above are similar to the case of the basic configuration example (FIG. 6A) of the second embodiment, and thus the description thereof will be omitted.

### <4. Configuration Example of Semiconductor Device Having Stress Alleviation Structure According to Third Embodiment>

Next, a configuration example of a semiconductor device having a stress alleviation structure according to a third embodiment will be described. In the present embodiment, one line portion 1043 is provided with a plurality of land portions 1044.

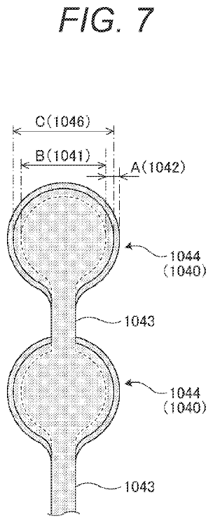

FIG. 7 illustrates an example in which any two land portions 1044 illustrated in FIGS. 5A and 5B are provided in one line portion 1043. With such a configuration, the wiring resistance at the connection portion of the land portion 1044 can be halved. In addition, even in a case where disconnection occurs in any of the terminals (the external terminal 1046 and the vias (not illustrated)) connected to the land portion 1044, the function can be maintained.

In addition, by including the second portion 1042 as illustrated in FIGS. 4A and 4B and FIGS. 5A and 5B described above, the degree of freedom of the wiring pattern 1040 and the external terminal 1046 or the via is further improved, and the stress can be effectively alleviated. Note that the external terminal 1046 or the via may be provided in each of the two land portions 1044, or may be provided in one of the two land portions 1044. Note that the wiring form of the line portion 1043 illustrated in FIG. 7 is an example, and is not limited to the wiring form of the figure.

### <5. Example of Method for Manufacturing Semiconductor Device Having Stress Alleviation Structure According to Second Embodiment>

### [Manufacturing Method According to Basic Configuration Example of Second Embodiment]

Next, a method for manufacturing the basic configuration example of the semiconductor device having the stress alleviation structure according to the second embodiment will be described with reference to the drawings. Note that, in the present basic configuration example, an example of a manufacturing method will be described in which a redistribution layer (including an aluminum pad) is formed on an outermost wiring layer on a silicon substrate 145 such as a semiconductor chip, and solder bumps as projecting electrodes are formed thereon.

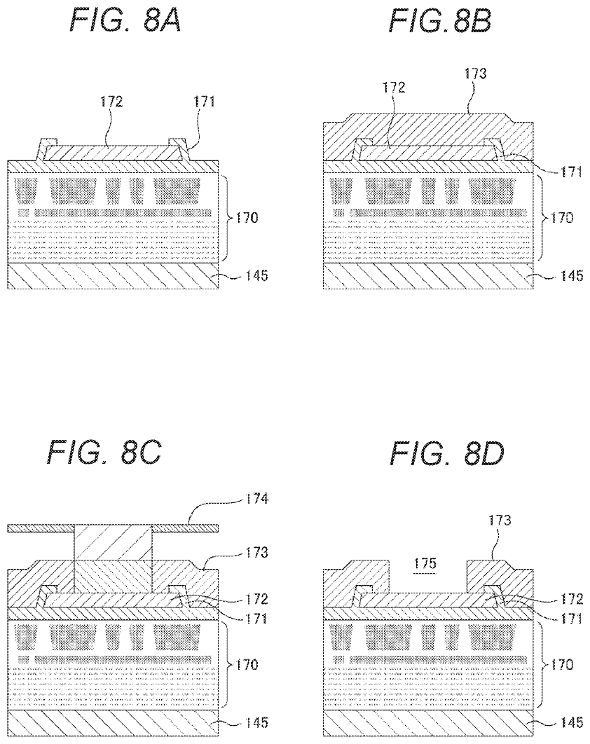

As illustrated in FIG. 8A, a redistribution layer 170 is formed on a silicon substrate 145, a passivation layer 171 opened in a substantially concave cross section is formed on the redistribution layer 170, and an aluminum (Al) pad 172 having a substantially flat plate shape is formed therein.

Next, as illustrated in FIG. 8B, the redistribution layer 170, the passivation layer 171, and the aluminum pad 172 are covered with a resin layer 173 such as photosensitive polyimide. Then, as illustrated in FIG. 8C, a predetermined region on the aluminum pad 172 is masked by a reticle 174 and exposed. When the exposure step is completed, the reticle 174 is removed, development is performed, and the exposed portion of the resin layer 173 is removed by etching as illustrated in FIG. 8D. As a result, an opening 175 is formed in a predetermined region on the aluminum pad 172.

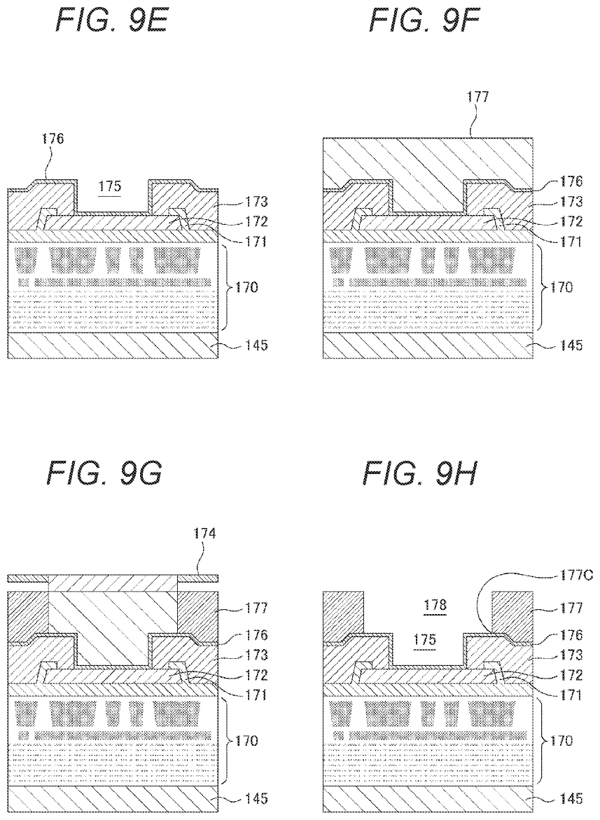

Next, as illustrated in FIG. 9E, a seed layer 176 constituted by a titanium-based metal is formed by sputtering or the like in the opening 175 having a predetermined region formed on the resin layer 173 and the aluminum pad 172.

Next, as illustrated in FIG. 9F, a photoresist 177 is applied onto the seed layer 176 constituted by a titanium-based metal by spin coating or the like. Then, as illustrated in FIG. 9G, a predetermined region including the opening 175 is masked by the reticle 174 and exposed. When the exposure step is completed, the reticle 174 is removed, development is performed, and an exposed portion of the photoresist 177 is removed by etching as illustrated in FIG. 9H. As a result, a stepped opening 178 having a larger diameter than the opening 175 is formed on the seed layer 176 in a predetermined region including the opening 175.

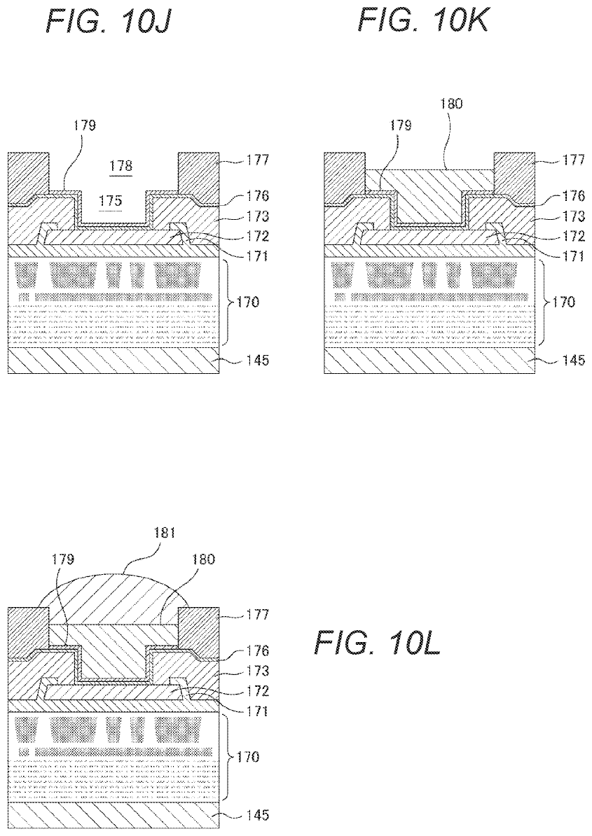

Next, as illustrated in FIG. 10J, copper plating is performed on the upper surface of the seed layer 176 in the stepped opening 178 including the opening 175 to form a copper UBM layer 179. Next, as illustrated in FIG. 10K, nickel (Ni) plating having a substantially reverse convex shape and filling the stepped opening 178 is performed on the copper UBM layer 179 to form a nickel UBM layer 180.

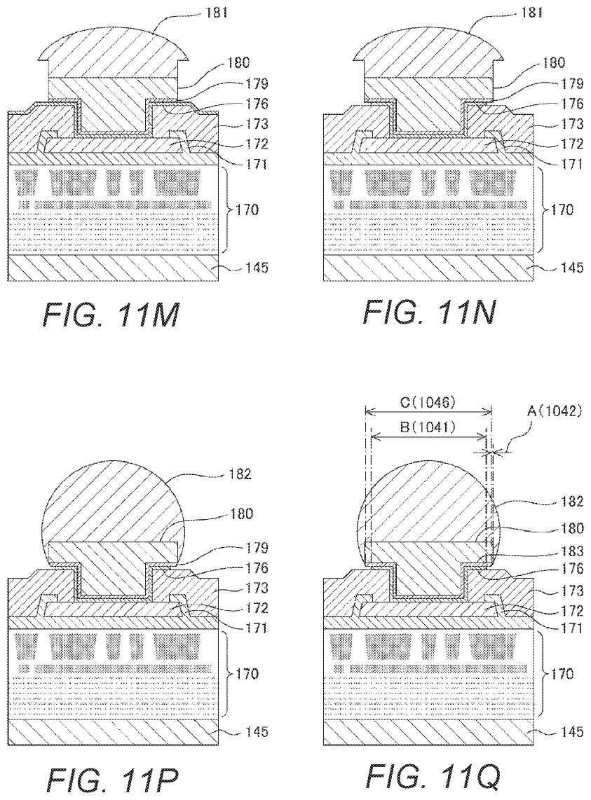

Next, as illustrated in FIG. 10L, solder is mounted on the nickel UBM layer 180 to form a solder bump 181. The solder bump 181 may be formed to be larger than the diameter of the stepped opening 178 and cover the photoresist 177. When the formation of the solder bump 181 is completed, the photoresist 177 is removed as illustrated in FIG. 11M.

Next, as illustrated in FIG. 11N, the seed layer 176 is over-etched to remove the titanium-based metal. As described in FIG. 4A in the basic configuration example of the first embodiment, the etching depth is the length of the second portion 1042 which is the non-contact portion (A) of copper corresponding to the wiring pattern 1040 of the land portion 1044 with the UBM layer 179. As a result, the first portion 1041 in contact with the seed layer 176 and the second portion 1042 in non-contact with the seed layer 176 are formed in the copper UBM layer 179 and the titanium seed layer 176.

Next, as illustrated in FIG. 11P, solder reflow is performed on the solder bump 181 on the nickel UBM layer 180 to form a BGA which is a ball-shaped external terminal 182.

As described above, the semiconductor device 500 having the stress alleviation structure according to the first embodiment can be manufactured.

In addition, it goes without saying that the present embodiment can be applied to the method for manufacturing the semiconductor device 500 having the stress alleviation structure according to the first embodiment by omitting the steps that do not correspond thereto.

Note that, in the present embodiment, the example of the manufacturing method in which the redistribution layer (including the aluminum pad) is formed on the outermost wiring layer on the semiconductor chip, and the solder bump 181 (including the ball-shaped external terminal 182) as the projecting electrode is directly formed on the redistribution layer has been described, but the redistribution layer of the second or more layers formed on the redistribution layer and the redistribution layer formed on the through mold via (TMV) can also be formed by the similar manufacturing method.

### [Manufacturing Method According to Modification (Part 1) of Second Embodiment]

Next, a manufacturing method for the modification (part 1) of the semiconductor device having the stress alleviation structure according to the second embodiment will be described with reference to the drawings. In the present modification, as illustrated in FIG. 6B, the end surface 1047 of the outer periphery of the copper UBM layer 179 is formed in a substantially tapered shape expanding upward.

In the method for manufacturing the semiconductor device having the stress alleviation structure according to the present modification, the positive photoresist 177 is applied onto the seed layer 176 constituted by a titanium-based metal by spin coating or the like in the photoresist application step illustrated in FIG. 9F. Then, as illustrated in FIG. 9G, a predetermined region including the opening 175 is masked by the reticle 174, and over-exposed. When the exposure step is completed, the reticle 174 is removed, and in FIG. 9H, over-development is performed to remove the exposed portion of the photoresist 177 by etching. Furthermore, depending on the material of the photoresist 177, for example, curing conditions such as adjusting the temperature to a low temperature or setting a profile are adjusted, and a heat treatment called curing for stabilizing the structure inside the material is performed.

As a result, the photoresist 177 can form a curved or tapered surface having a predetermined curvature on the peripheral surface of the stepped opening 178 and a peripheral edge portion 177c of the upper surface of the seed layer 176.

Next, the description of the intermediate step is omitted, and in FIG. 10J, copper plating is performed on the inner peripheral surface of the stepped opening 178 including the opening 175 to form the copper UBM layer 179. As a result, since copper plating is performed following the shape of the peripheral edge portion 177c of the bottom surface of the stepped opening 178, the end surface 1047 of the outer periphery of the copper UBM layer 179 is formed in a tapered shape. Thereafter, by removing the photoresist 177 and over-etching the seed layer 176, the end surface 1047 on the outer periphery of the UBM layer 179 can be formed in a tapered shape expanded upward. As a result, the first portion 1041 in contact with the seed layer 176 and the second portion 1042 in non-contact with the seed layer 176 are formed in the copper UBM layer 179 and the titanium seed layer 176.

Through the above manufacturing process, the end surface 1047 on the outer periphery of the UBM layer 179 can be formed in a tapered shape expanded upward as illustrated in FIG. 6B.

Note that the manufacturing process other than the above is the same as the method for manufacturing the semiconductor device having the stress alleviation structure according to the first embodiment, and thus the description thereof will be omitted.

### [Manufacturing Method According to Modification (Part 2) of Second Embodiment]

Next, a manufacturing method for a modification (part 2) of the semiconductor device having the stress alleviation structure according to the second embodiment will be described with reference to the drawings. In the present modification, as illustrated in FIG. 6C, instead of forming the UBM layer 179 by copper plating, the UBM layer 183 by copper sputtering is formed.

In FIG. 10J, instead of copper plating, copper sputtering is performed on the inner peripheral surface of the stepped opening 178 including the opening 175 to form the copper UBM layer 183.

Then, as illustrated in FIG. 11N, the seed layer 176 is over-etched using a chemical solution to remove only the titanium-based metal seed layer 176. As described in FIG. 4A in the basic configuration example of the first embodiment, the etching depth is the length of the second portion 1042 illustrated in FIG. 11Q which is the non-contact portion (A) of copper with the UBM layer 183. As a result, the first portion 1041 in contact with the seed layer 176 and the second portion 1042 in non-contact with the seed layer 176 are formed in the copper UBM layer 183 and the titanium seed layer 176.

With such a configuration, the effect of improving the degree of freedom of the external terminal 182 and alleviating the stress by the second portion 1042 can be enhanced, and the stress applied to the root portion of the external terminal 182 can be reduced. In a case where the external terminal 182 is only connected to the lower redistribution layer 170, copper sputtering is sufficient for forming the copper UBM layer 183, so that the cost can be reduced.

In the description of [Manufacturing Method According to Basic Configuration Example of Second Embodiment], the manufacturing process other than the above is the manufacturing method according to the present modification by replacing “copper plating” with “sputtering of copper”, replacing the “UBM layer 179” with the “UBM layer 183”, and replacing “FIG. 11P” with “FIG. 11Q”, and thus, the description thereof is omitted.

### <6. Wiring Pattern Example of Semiconductor Device Having Stress Alleviation Structure According to Present Disclosure>

### [Wiring Pattern Example (Part 1)]

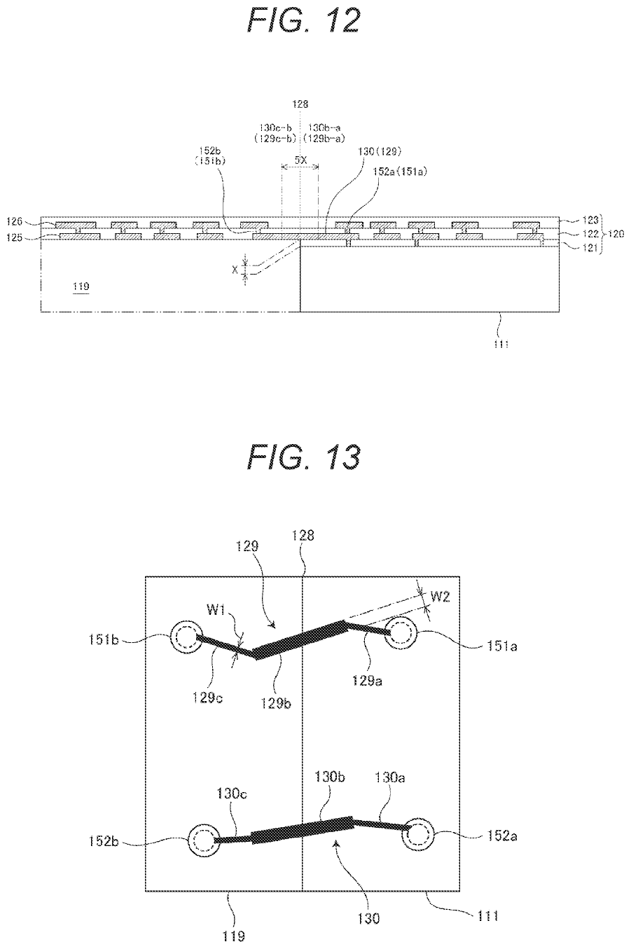

FIG. 13 is a schematic plan view of a wiring pattern example (part 1) in the front surface redistribution layer 120. FIG. 12 is a cross-sectional view of FIG. 13. Note that the actual front surface redistribution layer 120 is formed by laminating a large number of dielectric layers and wiring patterns, but is schematically illustrated for the sake of description, and detailed description is omitted. It similarly applies to the wiring pattern example (part 2) and subsequent wiring pattern examples.

As illustrated in FIGS. 12 and 13, the integrated circuit die 111 is fixed below the front surface redistribution layer 120. In addition, the dielectric layers 121, 122, and 123 and the wiring patterns 125 and 126 are alternately laminated on the front surface redistribution layer 120. Then, the integrated circuit die 111 and the front surface redistribution layer 120 are sealed with the sealing material 119 that is a molding compound (for example, epoxy resin). Thus, as illustrated in FIG. 13, the boundary 128 is formed between the integrated circuit die 111 and the front surface redistribution layer 120. Note that, in FIG. 12, the lower part of the portion of the front surface redistribution layer 120 not overlapping the integrated circuit die 111 is sealed with the sealing material 119, but may be hollow.

As illustrated in FIG. 12, the integrated circuit die 111 is electrically connected to the front surface redistribution layer 120 via vias 151a and 152a. The vias 151a and 152a are connected to vias 151b and 152b via wiring paths 129 and 130 formed between the dielectric layers 121 and 122. Then, the vias 151b and 152b are further connected to the redistribution layer thereon. Note that the wiring paths 129 and 130 illustrated in FIG. 13 may be arranged in wiring patterns of the same layer or may be arranged in wiring patterns of different layers.

The wiring paths 129, 130 extend across the boundary 128 between the integrated circuit die 111 and the sealing material 119, as illustrated in the plan view of FIG. 13. That is, the wiring paths 129 and 130 electrically and mechanically connect the conductive vias 151a and 152a on the integrated circuit die 111 and the conductive vias 151b and 152b in the sealing material 119 or on the sealing material 119.

Here, as described above, due to a mismatch in linear expansion coefficient between the material of the integrated circuit die 111 and the sealing material 119, or the like, a stress to curve at the boundary 128 between the integrated circuit die 111 and the sealing material 119 occurs. As a result, stress is also applied to the wiring paths 129 and 130 in the vicinity of the boundary 128.

It was observed that the occurrence rate of disconnection due to stress applied to the wiring paths 129 and 130 was reduced by changing the wiring widths of the wiring paths 129 and 130. Therefore, an object of the present wiring pattern example is to make the wiring width dimension orthogonal to the boundary 128 thicker than the wiring width dimensions of the other wiring path segments. Specifically, in FIG. 13, the wiring paths 129 and 130 are divided into three wiring path segments 129a, 129b, and 129c, and 130a, 130b, and 130c, respectively. Then, the wiring width dimension W2 of the wiring path segments 129b and 130b across the boundary 128 is twice the wiring width dimension W1 (for example, 5 μm) of the wiring path segments 129a, 129c, 130a, and 130c.

Here, it is advantageous to increase the wiring width dimension of the wiring path segments 129b and 130b from the viewpoint of preventing disconnection. However, from the viewpoint of wiring density, it is desirable that the wiring width dimension of the wiring path be small. Therefore, it is desirable that the lengths of the wiring path segments 129b and 130b having the wiring width dimension W2 (10 μm in this case) be as short as possible. In the example of FIG. 13, in a case where the distance from the upper surface of the integrated circuit die 111 to the wiring path (130 of FIG. 12) is X, when at least the wiring path segment 129b is extended by 5× (the actual measurement value in the case of the experimental example is 100 μm) around the boundary 128, the occurrence of the disconnection of the wiring path due to the stress can be suppressed.

In the case of the above configuration, it was observed that the disconnection rate can be reduced by 50% or more as compared with the case of W1=W2=5 μm.

Note that, in the example of FIG. 13, the bonding portions between the wiring path segments 129a and 129b, 129b and 129c, and the bonding portions between the wiring path segments 130a and 130b, 130b and 130c are formed such that the wiring widths are changed stepwise, but may be formed so as to be smoothly changed in a tapered shape.

### [Wiring Pattern Example (Part 2)]

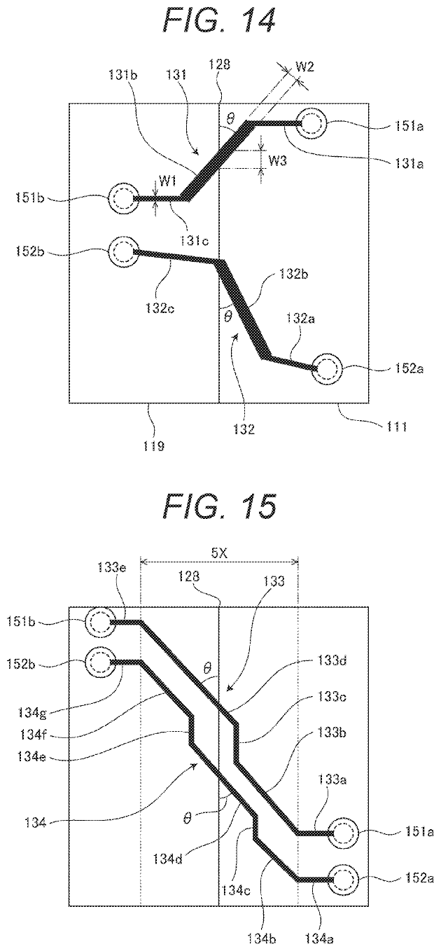

An object of the present wiring pattern example is to allow a wiring path across the boundary 128 to intersect the boundary 128 at an angle θ of 50 degrees or less. FIG. 14 is a schematic plan view of the present wiring pattern example in the front surface redistribution layer 120. The cross-sectional view corresponding to FIG. 14 is similar to FIG. 12, and thus description thereof is omitted. In the present wiring pattern example, similarly to FIG. 13, in FIG. 14, the wiring paths 131 and 132 are divided into three wiring path segments 131a, 131b, and 131c and three wiring path segments 132a, 132b, and 132c, respectively.

In FIG. 14, the wiring path 131 has an angle θ formed with the boundary 128 between the integrated circuit die 111 and the sealing material 119 of 50 degrees or less. In addition, the wiring path segments 132a and 132b of the wiring path 132 are bent on the boundary 128 in a state where the angle θ formed with the boundary 128 is set to an angle of 50 degrees or less different from the wiring path 131. Here, the angle θ formed with the boundary 128 refers to a narrow angle formed between the boundary 128 and the wiring path segment 131b or 132b as illustrated in FIG. 14.

In the case of such a configuration, it has been found that there is an effect of reducing the disconnection rate as compared with the case where the wiring path segments 131b and 132b are extended so as to be orthogonal to the boundary 128. The stress at the boundary 128 is mainly generated in the perpendicular direction (that is, the vertical direction) along the boundary 128.

In the example of the wiring path 131, the cross-sectional length W3 along the boundary 128 of the wiring path segment 131b is W3=W2/cos θ, and when 0 degrees<θ<90 degrees, 0<cos θ<1, so that W3>W2. Therefore, for example, when θ=45 degrees, W3 becomes √2 times of W2. That is, the cross-sectional length W3 along the boundary 128 is larger than the actual cross-sectional length W2. This is considered to be a cause of a decrease in the disconnection rate. In addition, also in the example of the wiring path 132, similarly to the case of the wiring path 131, the strength of the wiring path segment 132b at the bent portion is considered to be a cause of being stronger than the case of being orthogonal to the boundary 128.

Note that, in the present wiring pattern example, the angle formed with the boundary 128 is 50 degrees or less, but in view of only stress resistance, it can be said that the angle θ is preferably close to 0 degrees. However, from the viewpoint of balance with the wiring efficiency, the angle is preferably set to 30 degrees to 50 degrees. Furthermore, similarly to the wiring pattern example (part 1) of FIG. 13, the width W2 of each of the wiring path segments 131b and 132b may be increased (for example, twice the width W1 of the wiring path segment in the region other than the boundary 128) at the boundary 128. With this configuration, it is possible to further suppress occurrence of disconnection of the wiring paths 131 and 132 due to stress while suppressing a decrease in wiring density as much as possible.

### [Wiring Pattern Example (Part 3)]

An object of the present wiring pattern example is to eliminate the wiring segment orthogonal to the boundary 128 and to provide the shortest wiring having the angle θ of 50 degrees or less. FIG. 15 is a schematic plan view of the present wiring pattern example in the front surface redistribution layer 120. The cross-sectional view corresponding to FIG. 15 is similar to FIG. 12, and thus description thereof is omitted. In the present wiring pattern example, in FIG. 15, the wiring paths 133 and 134 are divided into five wiring path segments 133a to 133e and seven wiring path segments 134a to 134g, respectively.

In FIG. 15, in a case where a distance in the vertical direction from the upper surface of the integrated circuit die 111 to the wiring paths 133 and 134 is X (see FIG. 12), a region of at least 5× (100 μm in the present example) in a direction orthogonal to the boundary 128 as the center is considered as a region having a large stress. Therefore, in the region of 5X, all the wiring path segments 133b to 133d and 134b to 134f of the wiring paths 133 and 134 are extended such that the angle θ formed with the boundary 128 is 50 degrees or less (0 degrees are also included).

As described above, since the stress at the boundary 128 is mainly generated in the perpendicular direction (that is, the vertical direction) along the boundary 128, by adopting such a configuration, the stress resistance in all the wiring paths 133 and 134 in the vicinity of the boundary 128 can be improved.

In addition, the wiring path 133 extends along the boundary (in the 0 degree direction) at one location of the wiring path segment 133c, and the wiring path 134 extends along the boundary 128 at two locations of the wiring path segments 134c and 134e. By extending in this manner, the distances of the wiring path segments 133b, 133d, 134b, 134d, and 134f having angles other than 0 degrees with respect to the boundary 128 can be shortened, and the disconnection risk can be further reduced.

Note that, although the wiring width is constant (for example, W1=5 μm) in FIG. 15, it is also effective to make the width of each wiring path segment having an angle other than 0 degrees with respect to the boundary 128 larger than the widths of the other wiring path segments (for example, W2, double of W1=10 μm) in order to reduce the risk of disconnection.

### [Wiring Pattern Example (Part 4)]

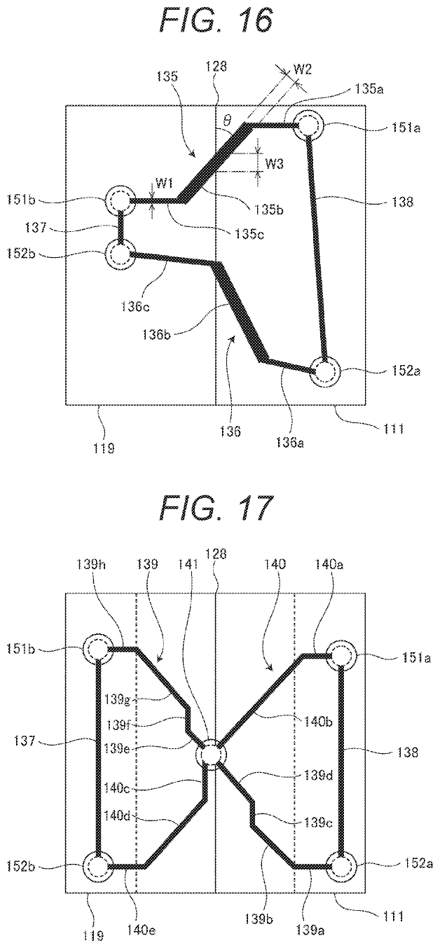

An object of the present wiring pattern example is to make the wiring path segment orthogonal to the boundary 128 a dual system. FIG. 16 is a schematic plan view of the present wiring pattern example in the front surface redistribution layer 120. The cross-sectional view corresponding to FIG. 16 is similar to FIG. 12, and thus description thereof is omitted. In the present wiring pattern example, as illustrated in FIG. 16, the wiring paths 135 and 136 are electrically connected to each other by the wiring paths 137 and 138 that do not cross the boundary 128 between the integrated circuit die 111 and the sealing material 119.

With this configuration, the wiring paths 135 and 136 become dual paths, and even in a case where any of the wiring paths 135 and 136 is disconnected, the function can be normally maintained.

In addition, in the present wiring pattern example, in the wiring paths 135 and 136, the wiring paths extend such that entry angles to the boundary 128 between the integrated circuit die 111 and the sealing material 119 are different from each other. With such a configuration, even in a case where a stress other than the orthogonal direction is generated in the boundary 128, the two wiring paths 135 and 136 are different in the direction of the angle θ, so that one of them can be expected to be sound. Therefore, the stress resistance of the wiring paths 135 and 136 as a whole can be improved.

### [Wiring Pattern Example (Part 5)]

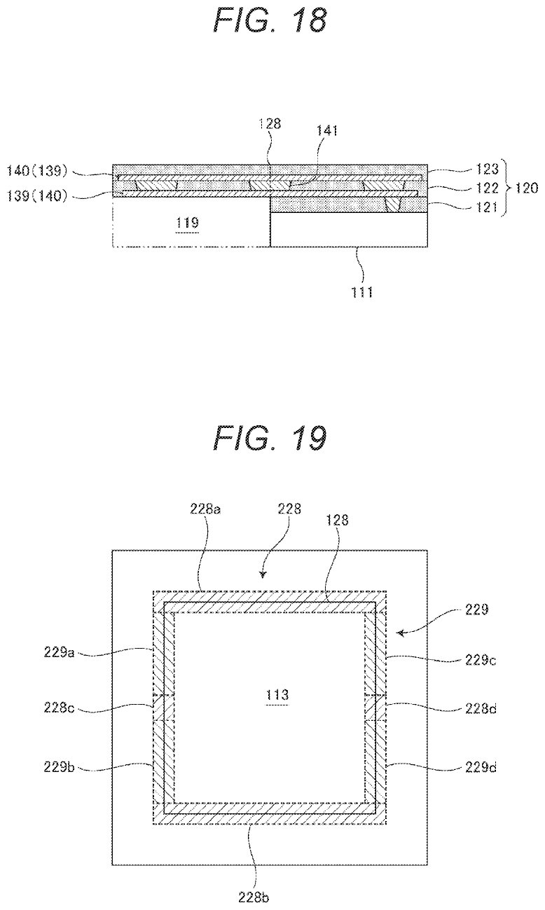

An object of the present wiring pattern example is to enhance stress resistance by disposing a relay via 141 at the boundary 128. FIG. 17 is a schematic plan view of the present wiring pattern example in the front surface redistribution layer 120. In addition, FIG. 18 illustrates a cross-sectional view corresponding to FIG. 17. Note that, in the figure, the lower part of the portion of the front surface redistribution layer 120 not overlapping the integrated circuit die 111 is sealed with the sealing material 119, but may be hollow.

In FIG. 16, an example has been described in which the wiring paths 135 and 136 are electrically connected to each other by the wiring paths 137 and 138 that do not cross the boundary 128 between the integrated circuit die 111 and the sealing material 119. In the present wiring pattern example, as illustrated in FIGS. 17 and 18, the wiring paths 139 and 140 are formed in different wiring layers, and are connected by the relay via 141 disposed at the boundary 128.

With this configuration, the stress generated at the boundary 128 is received by the relay via 141, and the stress resistance of the wiring paths 139 and 140 can be improved. In addition, as illustrated in FIG. 16, by extending the wiring paths 139 and 140 so as to have different entry angles into the boundary 128, it can be expected that one of the two wiring paths 139 and 140 is sound even in a case where stress other than in the orthogonal direction occurs at the boundary 128. Therefore, the stress resistance of the wiring paths 139 and 140 as a whole can be improved.

In addition, the wiring path segments 139a to 139d connected to the via 152a may be configured to extend to the upper layer, pass through the relay via 141 to the lower layer, and extend the wiring path segments 139e to 139h to the lower layer to be connected to the via 151b. Such routing of the wiring path is similar in the wiring path segments 140a to 140b and 140c to 140e.

In addition, as illustrated in FIG. 16, the vias 151b and 152b and the vias 151a and 152a may be electrically connected to each other by the wiring paths 137 and 138 that do not cross the boundary 128 between the integrated circuit die 111 and the sealing material 119. The effect of such connection is similar to that of the wiring pattern example (part 4) described above.

As described above, the wiring paths 129 to 140 described with reference to FIGS. 12 to 18 specifically constitute any of the wiring patterns 125, 126, and 127 formed on the dielectric layers 121, 122, 123, and 124 constituting the front surface redistribution layer 120 illustrated in FIG. 1. Therefore, it is also effective to extend the wiring patterns 125, 126, and 127 in a predetermined region of the boundary 128 at a low density at a position close to the integrated circuit die 111 (X in FIG. 12) and at a high density at a far position. This is because the stress from the boundary 128 decreases as the distance from the integrated circuit die 111 increases.

For example, in the front surface redistribution layer 120 of FIG. 1, the wiring pattern 125 is closest to the integrated circuit die 111, and the wiring pattern 127 is farthest. Therefore, the density of the wiring pattern 127 in the predetermined region of the boundary 128 is made larger than the density of the wiring pattern 125. By separating the wiring path 129 to 140 extending across the boundary 128 from the integrated circuit die 111 in this manner, resistance to stress can be improved, and eventually, disconnection can be suppressed.

Furthermore, by adopting the wiring path arrangement illustrated in any of FIGS. 12 to 18 described above only for a wiring pattern (in the front surface redistribution layer 120, for example, the wiring pattern 125) relatively close in distance from the integrated circuit die 111, resistance to stress can be improved.

Note that, in addition to the above wiring pattern examples, in a wiring pattern (in the front surface redistribution layer 120, for example, the wiring pattern 126 or 127) relatively far away from the integrated circuit die 111, a method for increasing wiring efficiency by setting a wiring path segment across the boundary 128 to have the same width (for example, W1 described above) as other wiring path segments is also useful from the viewpoint of achieving both wiring efficiency and stress resistance.

### <7. Power Supply Pattern Example of Semiconductor Device Having Stress Alleviation Structure According to Present Disclosure>

### [Power Supply Pattern Example (Part 1)]

An object of the present power supply pattern example is to provide a region for laying a power supply (VDD or GND) pattern (solid pattern or mesh pattern) on the boundary 128, thereby enhancing mechanical strength and thereby enhancing stress resistance. FIG. 19 is a schematic plan view of the present power supply pattern example in the front surface redistribution layer 120.

In FIG. 19, an inner quadrangular region indicates the semiconductor substrate 113, and an outer quadrangle indicates other regions. Note that the semiconductor substrate 113 may be the integrated circuit die 111. Furthermore, the four sides of the inner rectangle correspond to the boundary 128. A power supply pattern region 228 and a wiring pattern region 229 having a constant width on the boundary 128 are regions with large stress. The power supply pattern region 228 is a region where a power supply pattern (not illustrated) is laid, and is divided into four regions 228a to 228d, for example. Furthermore, the wiring pattern region 229 is a region in which a wiring path (not illustrated) extends, and is divided into four regions 229a to 229d, for example.

The power supply pattern is laid in a solid or mesh shape on a layer of a wiring pattern (in the front surface redistribution layer 120, for example, the wiring pattern 125) relatively close in distance from the integrated circuit die 111. With such a configuration, stress resistance can be improved, and power source stability and electromagnetic induction resistance can be improved.

### [Power Supply Pattern Example (Part 2)]

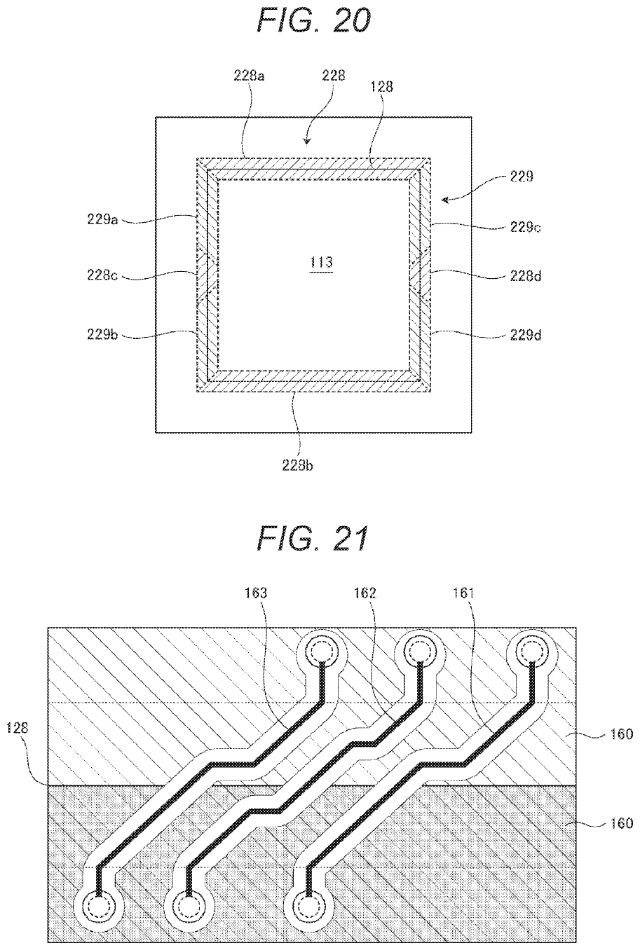

An object of the present power supply pattern example is to enhance the stress resistance by securing the power supply pattern region 228 in which the power supply (VDD or GND) pattern is disposed at the boundary 128 and the wiring pattern region 229 in which the angle θ formed by the wiring paths across the boundary 128 is 50 degrees or less. FIG. 20 is a schematic plan view of the present power supply pattern example in the front surface redistribution layer 120. Furthermore, the cross-sectional view corresponding to FIG. 20 is similar to FIG. 18.

In FIG. 20, since the configurations of the semiconductor substrate 113 in the inner quadrangular region, the outer quadrangle, the boundary 128, the regions 229a to 229d, and the regions 228a to 228d are similar to those in FIG. 19, the description thereof will be omitted.

FIG. 20 is different from FIG. 19 in that a boundary portion between the power supply pattern region 228 and the wiring pattern region 229 is formed obliquely. That is, in a case where the wiring path is routed at an angle θ formed with the boundary 128 of 50 degrees or less, the wiring path is routed from the upper left to the lower right or from the lower left to the upper right in FIG. 20 or in the opposite direction, that is, in the oblique direction. For this reason, the bonding portions of the regions 229a to 229d and the regions 228a to 228d are formed obliquely as illustrated in FIG. 20, so that the wiring efficiency is improved. Then, the power supply patterns and the wiring patterns (both not illustrated) are laid as the power supply pattern region 228 in the regions 228a to 228d, and the wiring pattern region 229 in the regions 229a to 229d.

By laying a solid or mesh-like power supply pattern in the regions 228a to 228d, wiring efficiency can be increased. In addition, with such a configuration, stress resistance can be improved, and power source stability and electromagnetic induction resistance can be improved. Note that, in FIG. 20, the regions 229a to 229d may be power supply pattern regions, and the regions 228a to 228d may be wiring pattern regions in which wiring paths extend.

### [Power Supply Pattern Example (Part 3)]

The purpose of the present power supply pattern example is to enhance the stress resistance by laying a power supply (VDD or GND) pattern in a margin region of a wiring path across the boundary 128. FIG. 21 is a schematic plan view of the present power supply pattern example in the front surface redistribution layer 120.

FIG. 21 illustrates an example in which the power supply pattern 160 and the signal wiring path 161 to 163 are mixed near the boundary 128. In FIG. 21, the power supply pattern 160 is laid between the three wiring paths 161 to 163 across the boundary 128. The power supply pattern 160 may be solid or mesh.

With this configuration, the solid or mesh-like power supply pattern 160 serves as an electromagnetic shield and also serves as a mechanical reinforcing member, so that the stress resistance of the wiring path 161 to 163 can be improved, and the power source stability and the electromagnetic induction resistance can be improved. Note that, in the above description, the front surface redistribution layer 120 has been described as an example, but a similar configuration can be adopted in the back surface redistribution layer 107.

As described above, the wiring pattern example and the power supply pattern example of the semiconductor device having the stress alleviation structure according to the present disclosure can be applied to any wiring path arranged in the region facing the integrated circuit die 111. That is, by configuring the wiring path existing in the vicinity of the boundary 128 overlapping the edge of the integrated circuit die 111 in the wiring layer of each substrate as described above, it is possible to provide the semiconductor device 500 in which stress can be alleviated and reliability of wiring connection is improved.

<8. Example of Semiconductor Device to which Stress Alleviation Structure According to Present Disclosure is Applicable>

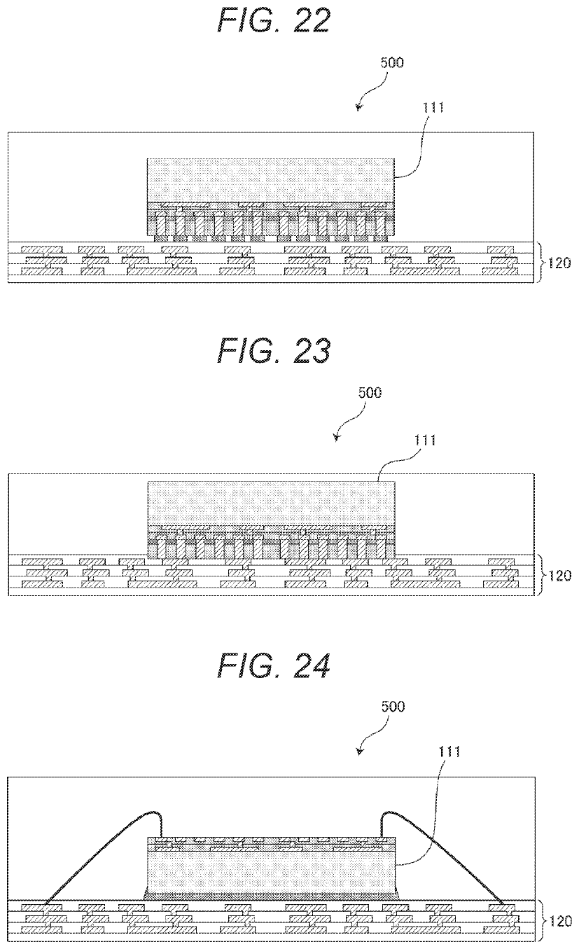

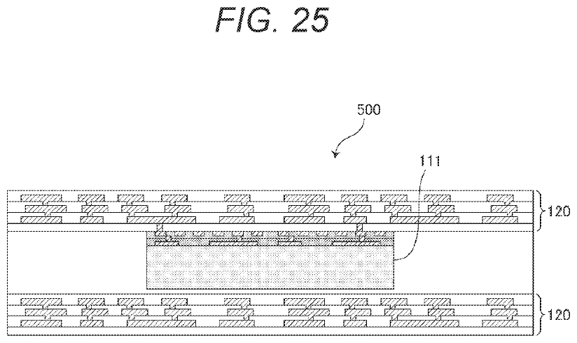

The semiconductor device 500 to which the stress alleviation structure according to the present disclosure is applicable is configured as described above. Therefore, as illustrated in FIG. 22, the structure according to the present disclosure can be applied to a wiring layer on a printed circuit board on which a wafer level chip size package (WLCSP) chip is mounted. Further, as illustrated in FIG. 23, the present invention can be applied to a wiring layer of an interposer board of a fine pitch ball grid array (FBGA) package adopting flip-chip connection by C4 bumps. Further, as illustrated in FIG. 24, the present invention can be applied to a wiring layer of an interposer board of an FBGA package adopting wire bonding connection. Furthermore, as illustrated in FIG. 25, the present invention can also be applied to an IC mounting substrate in which an integrated circuit die 111 is mounted in a substrate.

Furthermore, the present application example is not limited to the example of the semiconductor device 500 described above, and can be applied to a semiconductor device 500 having a wiring pattern to which stress due to a difference in linear expansion coefficient is applied, an external terminal such as a through via, a conductive pillar, or a solder ball to which stress is applied to a root portion thereof, or any wiring path arranged in a region facing an integrated circuit die.

The description of the above-described embodiments is an example of the present technology, and the present technology is not limited to the above-described embodiments. For this reason, it is needless to say that various modifications other than the above-described embodiments can be made according to the design and the like without departing from the technical idea according to the present disclosure. In addition, the effects described in the present specification are merely examples and are not limited, and other effects may be provided. In addition, the configurations of the basic configuration examples and the modifications of the above-described embodiments, the wiring pattern examples, or the power supply pattern examples can be appropriately combined.

Note that the present technology can have the following configurations.
(1)

A semiconductor device including:
a first dielectric layer;
a seed layer having a first land portion formed on the first dielectric layer;
a second land portion formed on the seed layer and having a diameter larger than a diameter of the first land portion that can be connected to a wiring pattern;
an external terminal formed on the second land portion; and
a second dielectric layer covering the seed layer, the first land portion, and the second land portion.
(2)

The semiconductor device according to (1), in which the wiring pattern is formed by forming a land portion formed on the seed layer in a substantially circular shape in plan view and extending a line portion.
(3)

The semiconductor device according to (2), in which the wiring pattern is formed by connecting land portions formed on two of the seed layer formed in the substantially circular shape in plan view in series and extending a line portion.
(4)

The semiconductor device according to (1), in which a land portion formed on the seed layer is formed in a substantially tapered shape expanded upward.
(5)

A semiconductor device including:
a conductive pad recessed in a passivation layer;
a seed layer having a land portion formed on the conductive pad;
an under bump metal layer including upper and lower two layers formed on the seed layer;
an external terminal formed on the under bump metal layer; and
a dielectric layer covering a peripheral surface of the under bump metal layer, in which a diameter of a lower layer of the under bump metal layer is formed to be larger than a diameter of the land portion of the seed layer.
(6)

The semiconductor device according to (5), in which a lower layer of the under bump metal layer formed on the seed layer is formed in a substantially tapered shape expanded upward.
(7)

A method for manufacturing a semiconductor device including:
forming a redistribution layer on a silicon substrate and forming a conductive pad thereon;
covering the redistribution layer with a resin film and forming an opening on the conductive pad;
forming a conductive seed layer on the opening of the conductive pad and an upper surface of the resin film;
forming an under bump metal layer of a conductor on the seed layer in the opening of the conductive pad;
forming a solder bump on the under bump metal layer; and
performing side edging on the seed layer to form a diameter of a lower layer of the under bump metal layer larger than a diameter of a land portion formed by the seed layer.
(8)

The method for manufacturing a semiconductor device according to (7), in which the forming the under bump metal layer includes performing copper plating on a lower layer and nickel plating on an upper layer.
(9)

The method for manufacturing a semiconductor device according to (7), in which the forming the under bump metal layer includes performing sputtering of copper on a lower layer and nickel plating on an upper layer.
(10)

The method for manufacturing a semiconductor device according to (7), in which the forming the under bump metal layer includes forming an end surface of an outer periphery of a lower under bump metal layer in a tapered shape expanded upward.

### REFERENCE SIGNS LIST

101 Carrier substrate
102 Release layer
103, 105 Dielectric layer
104 Wiring pattern
106 Through via
107 Back surface redistribution layer
108 Opening
111 Integrated circuit die
112 Adhesive
113 Semiconductor substrate
114 Interconnect structure
115 Pad
116 Passivation film
117 Die connector
118 Dielectric material
119 Sealing material
120 Front surface redistribution layer
121 to 124 Dielectric layer
125 to 127 Wiring pattern
128 Boundary
129 to 140 Wiring path
141 Relay via
142 Under bump metal (UBM)
143 Conductive connector
144 Tape
145 Silicon substrate
151a, 151b, 152a, 152b Conductive via
160 Power supply pattern
161 to 163 Wiring path
171 Passivation layer
172 Aluminum pad
173 Resin layer
174 Reticle
175 Opening
176 (Seed Layer)
177 Photoresist
177c Peripheral edge
178 Stepped opening
179, 183 Under bump metal layer (UBM layer of copper)
180 Under bump metal layer (UBM layer of nickel)
181 Solder bump
182 External terminal
210 End surface
228 Power supply pattern region
229 Wiring pattern region
300 Package
301 First package region
302 Second package region
500 Semiconductor device
1040 Wiring pattern
1030, 1050 Dielectric layer
1041 First portion
1042 Second portion
1043 Line portion
1044 Land portion
1045 (Seed Layer)
1046 External terminal
1047 End surface
θ Angle

What is claimed is:

1. A semiconductor device, comprising:
a first dielectric layer;
a seed layer having a first land portion formed on the first dielectric layer;
a second land portion formed on the seed layer and having a diameter larger than a diameter of the first land portion that can be connected to a wiring pattern;
an external terminal formed on the second land portion; and
a second dielectric layer covering the seed layer, the first land portion, and the second land portion.

2. The semiconductor device according to claim 1, wherein the wiring pattern is formed by forming a land portion formed on the seed layer in a substantially circular shape in plan view and extending a line portion.

3. The semiconductor device according to claim 2, wherein the wiring pattern is formed by connecting land portions formed on two of the seed layer formed in the substantially circular shape in plan view in series and extending a line portion.

4. The semiconductor device according to claim 1, wherein a land portion formed on the seed layer is formed in a substantially tapered shape expanded upward.

5. A semiconductor device, comprising:
a conductive pad recessed in a passivation layer;
a seed layer having a land portion formed on the conductive pad;
an under bump metal layer including upper and lower two layers formed on the seed layer;
an external terminal formed on the under bump metal layer; and
a dielectric layer covering a peripheral surface of the under bump metal layer, wherein a diameter of a lower layer of the under bump metal layer is formed to be larger than a diameter of the land portion of the seed layer.

6. The semiconductor device according to claim 5, wherein a lower layer of the under bump metal layer formed on the seed layer is formed in a substantially tapered shape expanded upward.

7. A method for manufacturing a semiconductor device, comprising:
forming a redistribution layer on a silicon substrate and forming a conductive pad thereon;
covering the redistribution layer with a resin film and forming an opening on the conductive pad;
forming a conductive seed layer on the opening of the conductive pad and an upper surface of the resin film;
forming an under bump metal layer of a conductor on the seed layer in the opening of the conductive pad;
forming a solder bump on the under bump metal layer; and
performing side edging on the seed layer to form a diameter of a lower layer of the under bump metal layer larger than a diameter of a land portion formed by the seed layer.

8. The method for manufacturing a semiconductor device according to claim 7, wherein the forming the under bump metal layer includes performing copper plating on a lower layer and nickel plating on an upper layer.

9. The method for manufacturing a semiconductor device according to claim 7, wherein the forming the under bump metal layer includes performing sputtering of copper on a lower layer and nickel plating on an upper layer.

10. The method for manufacturing a semiconductor device according to claim 7, wherein the forming the under bump metal layer includes forming an end surface of an outer periphery of a lower under bump metal layer in a tapered shape expanded upward.
